(19) United States
(12) Patent Application Publication
(10) Pub. No.: US 2024/0429226 A1
(43) Pub. Date: Dec. 26, 2024

(54) PROTECTION DIODE FOR STACKED FIELD EFFECT TRANSISTOR

(71) Applicant: International Business Machines Corporation, Armonk, NY (US)

(72) Inventors: HUIMEI ZHOU, Albany, NY (US); Chen Zhang, Santa Clara, CA (US); Shahrukh Khan, Sandy Hook, CT (US); Albert M. Chu, Nashua, NH (US); Anthony I. Chou, Guilderland, NY (US); Junli Wang, Slingerlands, NY (US)

(21) Appl. No.: 18/337,867

(22) Filed: Jun. 20, 2023

(51) Int. Cl. H01L 27/02; H01L 21/822; H01L 21/8238; H01L 27/092; H01L 29/06; H01L 29/423; H01L 29/66; H01L 29/775

(52) U.S. Cl. CPC H01L 27/0255; H01L 21/8221; H01L 21/823807; H01L 21/823814; H01L 21/823871; H01L 27/0922; H01L 29/0673; H01L 29/42392; H01L 29/66439; H01L 29/775

(57) ABSTRACT

Embodiments are disclosed for a semiconductor structure. The semiconductor structure includes a protection diode. The protection diode includes a substrate, a gate, a first nanosheet layer, and a second nanosheet layer. The first nanosheet layer includes a heavily doped n-type epitaxial disposed over the substrate. Additionally, the first nanosheet layer is in contact with the gate. Further, the second nanosheet layer includes a heavily doped p-type epitaxial disposed over the substrate. Additionally, the second nanosheet layer is in contact with the gate. Further, the first nanosheet layer and the second nanosheet layer surround the gate.

### BACKGROUND

The present invention generally relates to protection diodes, and more particularly to a protection diode for a stacked field effect transistor (FET).

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node.

A potential solution to this chip scaling problem is gate all around technology. One example of a complex gate all around technology is a complementary FET (CFET) where n-type FET (nFET) and p-type FET (pFET) nanowires/nanosheets are vertically stacked on top of each other.

### SUMMARY

Embodiments are disclosed for a semiconductor structure. The semiconductor structure includes a protection diode. The protection diode includes a substrate, a gate, a first nanosheet layer, and a second nanosheet layer. The first nanosheet layer includes a heavily doped n-type epitaxial disposed over the substrate. Additionally, the first nanosheet layer is in contact with the gate. Further, the second nanosheet layer includes a heavily doped p-type epitaxial disposed over the substrate. Additionally, the second nanosheet layer is in contact with the gate. Further, the first nanosheet layer and the second nanosheet layer surround the gate.

The present Summary is not intended to illustrate each aspect of, every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1A is a cross-sectional view of example protection diodes, in accordance with some embodiments of the present disclosure.

FIG. 1B is a cross-sectional view of example protection diodes, in accordance with some embodiments of the present disclosure.

FIG. 1C is a top view of example protection diodes, in accordance with some embodiments of the present disclosure.

FIG. 2 is a cross-sectional view of a semiconductor structure having an example protection diode, in accordance with some embodiments of the present disclosure.

FIG. 3-1 is a cross-sectional view of a semiconductor structure during an intermediate step of a method of fabricating a protection diode and a stacked FET, in accordance with some embodiments of the present disclosure.

FIG. 3-2 is a cross-sectional view of a semiconductor structure during an intermediate step of a method of fabricating a protection diode and a stacked FET, in accordance with some embodiments of the present disclosure.

FIG. 3-3 is a cross-sectional view of a semiconductor structure during an intermediate step of a method of fabricating a protection diode and a stacked FET, in accordance with some embodiments of the present disclosure.

FIG. 3-4 is a cross-sectional view of a semiconductor structure during an intermediate step of a method of fabricating a protection diode and a stacked FET, in accordance with some embodiments of the present disclosure.

FIG. 3-5 is a cross-sectional view of a semiconductor structure during an intermediate step of a method of fabricating protection diodes and a stacked FET, in accordance with some embodiments of the present disclosure.

FIG. 3-6 is a cross-sectional view of a semiconductor structure during an intermediate step of a method of fabricating protection diodes and a stacked FET, in accordance with some embodiments of the present disclosure.

FIG. 3-7 is a cross-sectional view of a semiconductor structure during an intermediate step of a method of fabricating protection diodes and a stacked FET, in accordance with some embodiments of the present disclosure.

FIG. 3-8 is a cross-sectional view of a semiconductor structure during an intermediate step of a method of fabricating protection diodes and a stacked FET, in accordance with some embodiments of the present disclosure.

FIG. 4 is a process flow chart of a method for fabricating a protection diode and a stacked FET, in accordance with some embodiments of the present disclosure.

FIG. 5-1 is a cross-sectional view of a semiconductor structure during an intermediate step of a method of fabricating a protection diode and a stacked FET, in accordance with some embodiments of the present disclosure.

FIG. 5-2 is a cross-sectional view of a semiconductor structure during an intermediate step of a method of fabricating a protection diode and a stacked FET, in accordance with some embodiments of the present disclosure.

FIG. 5-3 is a cross-sectional view of a semiconductor structure during an intermediate step of a method of fabricating a protection diode and a stacked FET, in accordance with some embodiments of the present disclosure.

FIG. 5-4 is a cross-sectional view of a semiconductor structure during an intermediate step of a method of fabricating a protection diode and a stacked FET, in accordance with some embodiments of the present disclosure.

FIG. 5-5 is a cross-sectional view of a semiconductor structure during an intermediate step of a method of fabricating a protection diode and a stacked FET, in accordance with some embodiments of the present disclosure.

FIG. 5-6 is a cross-sectional view of a semiconductor structure during an intermediate step of a method of fabricating a protection diode and a stacked FET, in accordance with some embodiments of the present disclosure.

FIG. 5-7 is a cross-sectional view of a semiconductor structure during an intermediate step of a method of fabricating a protection diode and a stacked FET, in accordance with some embodiments of the present disclosure.

FIG. 5-8 is a cross-sectional view of a semiconductor structure during an intermediate step of a method of fabricating a protection diode and a stacked FET, in accordance with some embodiments of the present disclosure.

FIG. 6 is a process flow chart of a method for fabricating a protection diode and a stacked FET, in accordance with some embodiments of the present disclosure.

FIG. 7-1 is a cross-sectional view of a semiconductor structure during an intermediate step of a method of fabricating a protection diode and a stacked FET, in accordance with some embodiments of the present disclosure.

FIG. 7-2 is a cross-sectional view of a semiconductor structure during an intermediate step of a method of fabricating a protection diode and a stacked FET, in accordance with some embodiments of the present disclosure.

FIG. 7-3 is a cross-sectional view of a semiconductor structure during an intermediate step of a method of fabricating a protection diode and a stacked FET, in accordance with some embodiments of the present disclosure.

FIG. 7-4 is a cross-sectional view of a semiconductor structure during an intermediate step of a method of fabricating a protection diode and a stacked FET, in accordance with some embodiments of the present disclosure.

FIG. 7-5 is a cross-sectional view of a semiconductor structure during an intermediate step of a method of fabricating a protection diode and a stacked FET, in accordance with some embodiments of the present disclosure.

FIG. 7-6 is a cross-sectional view of a semiconductor structure during an intermediate step of a method of fabricating a protection diode and a stacked FET, in accordance with some embodiments of the present disclosure.

FIG. 7-7 is a cross-sectional view of a semiconductor structure during an intermediate step of a method of fabricating a protection diode and a stacked FET, in accordance with some embodiments of the present disclosure.

FIG. 7-8 is a cross-sectional view of a semiconductor structure during an intermediate step of a method of fabricating a protection diode and a stacked FET, in accordance with some embodiments of the present disclosure.

FIG. 7-9 is a cross-sectional view of a semiconductor structure during an intermediate step of a method of fabricating a protection diode and a stacked FET, in accordance with some embodiments of the present disclosure.

FIG. 7-10 is a cross-sectional view of a semiconductor structure during an intermediate step of a method of fabricating a protection diode and a stacked FET, in accordance with some embodiments of the present disclosure.

FIG. 8 is a process flow chart of a method for fabricating a protection diode and a stacked FET, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the example embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub lithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device having a dummy fin removed from within an array of tight pitch fins according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

As stated previously, in complementary FET designs, nFET and pFET nanowires and/or nanosheets are vertically stacked on top of each other. However, it can be challenging to form protection diodes to protect the pFET because of the unique design and architecture of stacked FETs. A diode is a semiconductor device that allows current to flow more easily in one direction than the opposite direction. Further, the diode restricts current from flowing in the opposite direction. As such, a protection diode can be a diode that mitigates plasma induced damage (PID), or the effects of electrostatic discharge (ESD), by directing current away from the FETs that the diode is protecting.

Accordingly, some embodiments of the present disclosure provide protection diodes for stacked FETs and a method to fabricate the protection diodes. In this way, such embodiments can improve the operation of stacked FET semiconductor devices. More specifically, such embodiments make it possible to fabricate protection diodes for stacked FETs, which mitigate potential PID to the nFETs and/or pFETs. However, it is noted that some embodiments may not have these potential advantages. Further, these potential advantages are not necessarily required of all embodiments of the present disclosure.

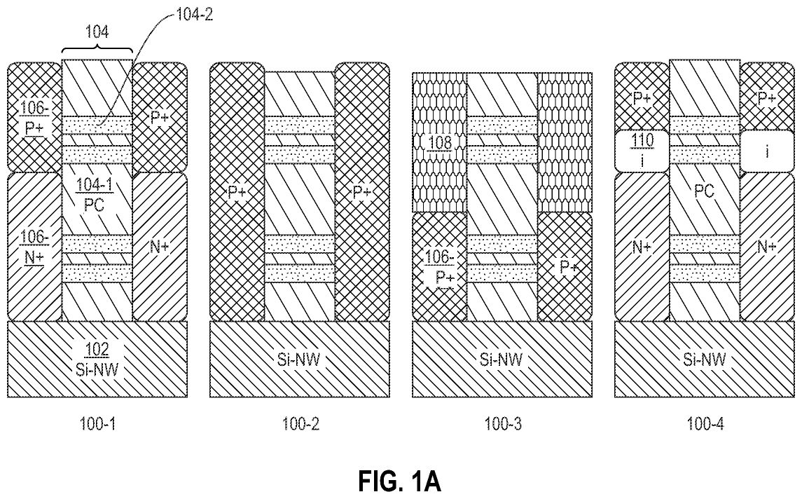

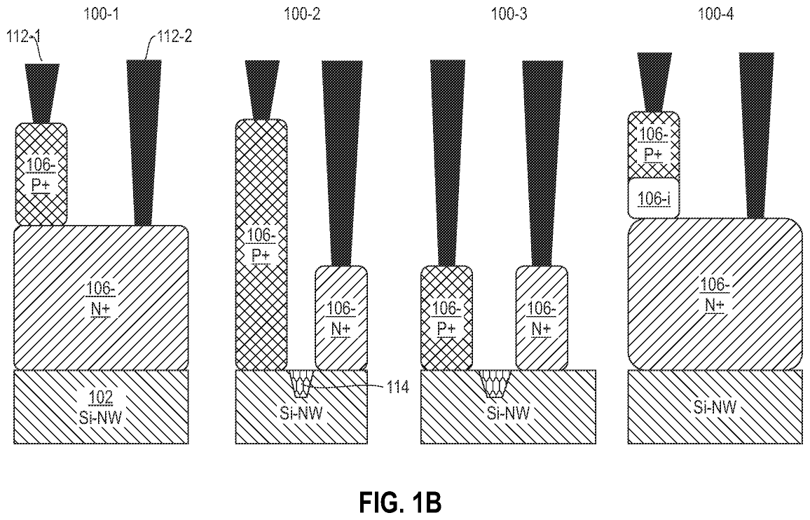

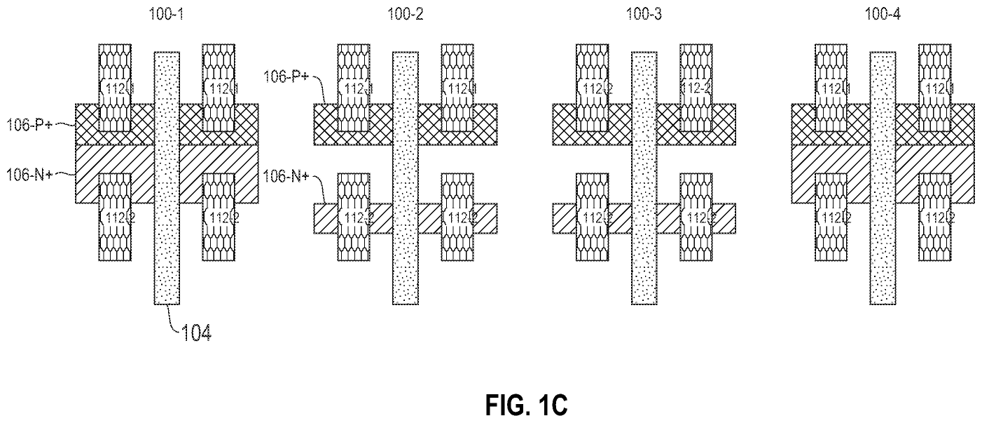

FIG. 1A is a cross-sectional view of example protection diodes 100-1, 100-2, 100-3, 100-4 (collectively referred to as example protection diodes 100), in accordance with some embodiments of the present disclosure. This cross-sectional view is a cross-P+C view. In such embodiments, the example protection diodes 100 can provide protection from ESD and PID for nFETs and pFETs in a stacked FET semiconductor structure.

The example protection diode 100-1 includes parallel vertical structures of n-type and p-type epitaxies in nanosheet stacks that are self-aligned to a gate. More specifically, the example protection diode 100-1 includes a substrate 102, gate 104, which include stacked sheet from bottom to top, layers 106-N+, and layers 106-P+. The substrate 102 may be composed of silicon (Si) nanowires (NW). Further, the gate 104 may include gate material 104-1 and channels 104-2. The layers 106-N+ may be heavily N doped epitaxies disposed over the substrate 102. The layers 106-P+ may be heavily P doped epitaxies disposed over the heavily N doped epitaxies.

The example protection diode 100-2 includes a scaled protection diode with vertical structures of p-type epitaxies that are self-aligned to the gate 104. More specifically, the example protection diode 100-2 includes substrate 102, gate 104, which include stacked sheet from bottom to top, and layers 106-P+. The layers 106-P+ may be heavily P doped layers disposed over the substrate 102.

The example protection diode 100-3 includes a scaled protection diode with vertical structures of p-type epitaxies that are self-aligned to a gate 104 with no stacked epitaxies in the top nanosheet stack. More specifically, the example protection diode 100-3 includes substrate 102, gate 104, layers 106-P+, and interlayer dielectric (ILD) 108. The layers 106-P+ may be a P doped layer disposed over the substrate 102.

The example protection diode 100-4 includes a scaled PIN protection diode with vertical structures that are self-aligned to the gate 104, which include stacked sheet from bottom to top. The example protection diode 100-4 includes substrate 102, layers 106-N+, intrinsic layer 110-i, and layers 106-P+. The intrinsic layer 110-i is an undoped epitaxial layer disposed between the heavily doped P epitaxies of the layers 106-P+ and the heavily doped N epitaxies of the layers 106-N+.

FIG. 1B is a cross-sectional view of the example protection diodes 100-1, 100-2, 100-3, 100-4, in accordance with some embodiments of the present disclosure. This cross-sectional view is a cross-epitaxial view.

In this view, the example protection diode 100-1 includes shallow epitaxial contact 112-1 disposed over the layer 106-P+, deep epitaxial contact 112-2 disposed over layer 106-N+, which, as stated previously is disposed over the substrate 102. Further, the epitaxial contacts 112-1, 112-2 are metal filled contacts.

Similarly, the example protection diode 100-2 includes shallow epitaxial contact 112-1 disposed over the layer 106-P+, and deep epitaxial contact 112-2 disposed over layer 106-N+. Additionally, the height of layer 106-P+ is higher than height of layer 106-N+k, thus providing more nanosheet channels through the epitaxy of the layer 106-P+ than that of the layer 106-N+. Additionally, the example protection diode 100-2 includes an interlayer dielectric 114 disposed within the substrate 102. The interlayer dielectric 114 can represent an isolation layer that isolates the layer 106-P+ from the layer 106-N+.

Further, the example protection diode 100-3 includes epitaxial contact 112 disposed over the layer 106-P+, and an epitaxial contact 112 disposed over layer 106-N+. Additionally, the example protection diode 100-3 includes an interlayer dielectric 114 disposed within the substrate 102. The interlayer dielectric 114 can represent an isolation layer that isolates the layer 106-P+ from the layer 106-N+.

As stated previously, the example protection diode 100-4 includes a PIN protection diode. Further, the example protection diode 100-4 include an epitaxial contact 112 disposed over the layer 106-P+, and an epitaxial contact 112 disposed over the layer 106-N+.

FIG. 1C is a top view of example protection diodes 100-1, 100-2, 100-3, 100-4, in accordance with some embodiments of the present disclosure. In this view, the example protection diode 100-1 includes gate 104, layer 106-P+, layer 106-N+, and epitaxial contacts 112. Similarly, the example protection diode 100-2 includes gate 104, layer 106-P+, layer 106-N+, and epitaxial contacts 112. Additionally, the example protection diode 100-3 includes gate 104, layer 106-P+, and layer 106-N+. Further, the example protection diode 100-4 includes gate 104, layer 106-P+, and layer 106-N+.

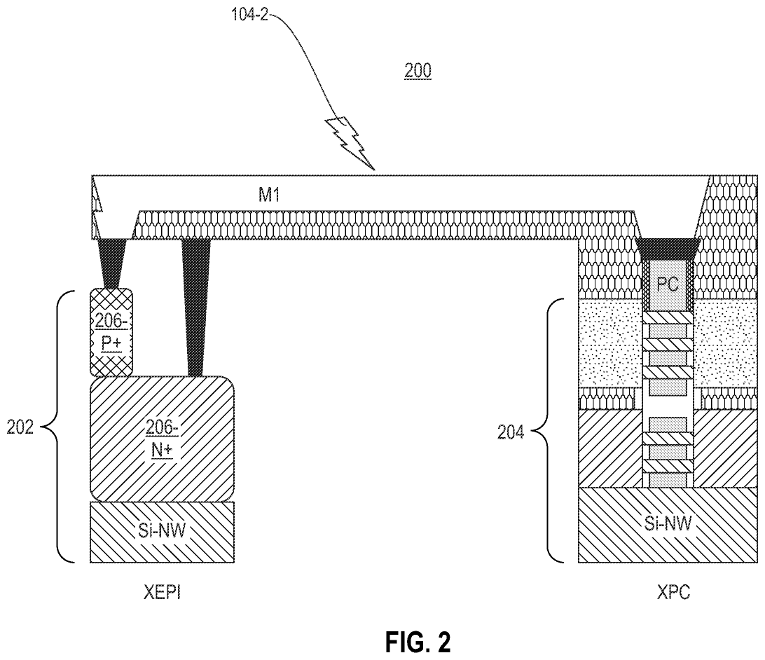

FIG. 2 is a cross-sectional view of an example semiconductor structure 200 having an example protection diode 202, in accordance with some embodiments of the present disclosure. The semiconductor structure 200 includes the example protection diode 202, metal line M1, and stacked FET 204. The example protection diode 202 can be similar to the example protection diode 100-1, and represents a cross-epitaxial (XEPI) view. Similar to the example protection diode 100-1, the example protection diode 202 includes layers 206-P+, 206-N+. The stacked FET 204 can represent a cross-gate view (XPC).

According to some embodiments of the present disclosure, a plasma damage 208 can result from a high positive or high negative charge emanating from BEOL process. However, the example protection diode 202 can allow the current to release from the layers 206-P+, 206-N+ of the example protection diode 202. In this way, the plasma damage may be released at the example protection diode 202, without impacting the stacked FET 204 in the event of a high positive charge. Additionally, in the event of a high negative charge, the example protection diode 202 can allow the current to release from the layers 106-P+, 106-N+ at reverse BD. In this way the example protection diode 202 can protect the gate oxide of the stacked FET 204.

The example semiconductor structure 200 includes an example protection diode 202 similar to the example protection diode 100-1. However, according to some embodiments of the present disclosure, other example protection diodes (e.g., example protection diodes 100-2, 100-3, 100-4) may be incorporated into the example semiconductor structure 200 and also junction type of wiring connection could be reversed.

Embodiments described herein enable the fabrication of stacked FET semiconductor structures that have ESD and PID protection devices formed in the same process flow. Herein, a method of forming such a device and the resulting structure is described and the process is performed in a same process flow as that used to form one or more stacked FETs that the diode is protecting.

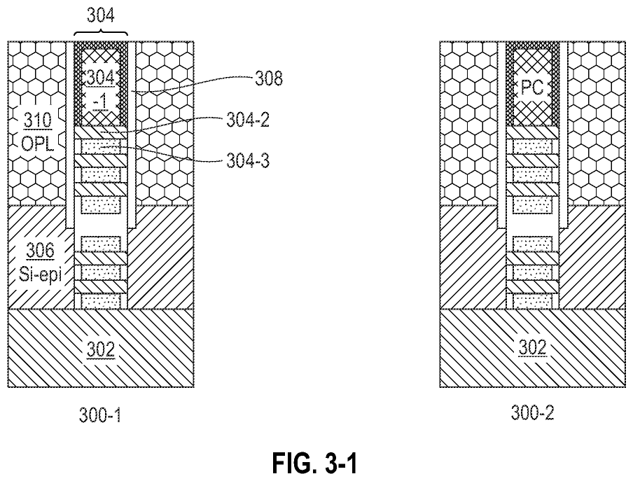

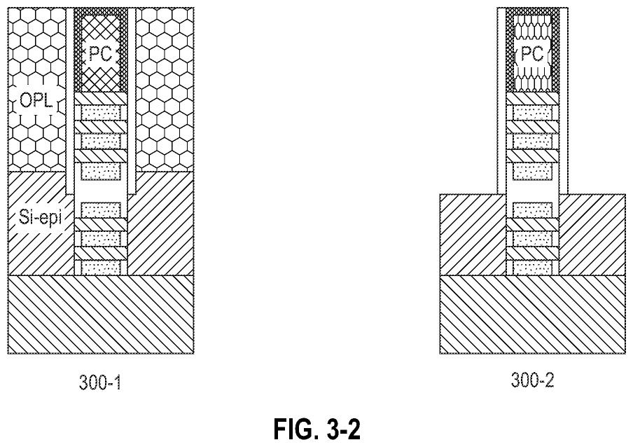

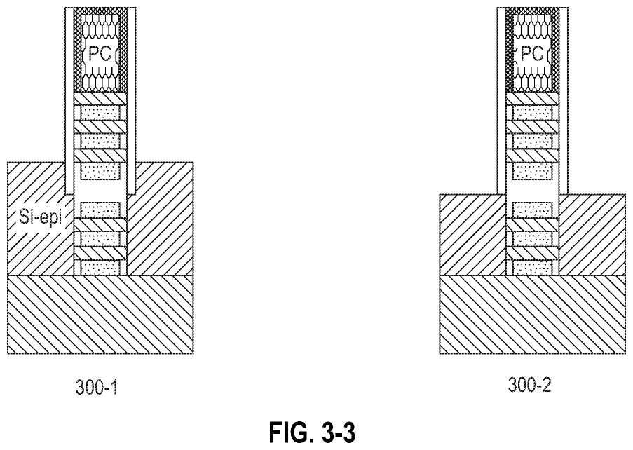

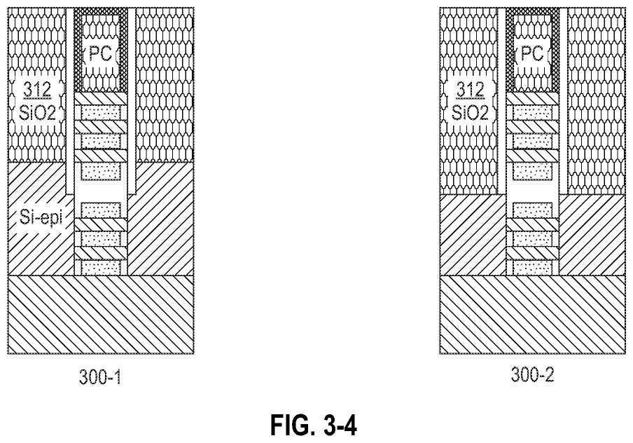

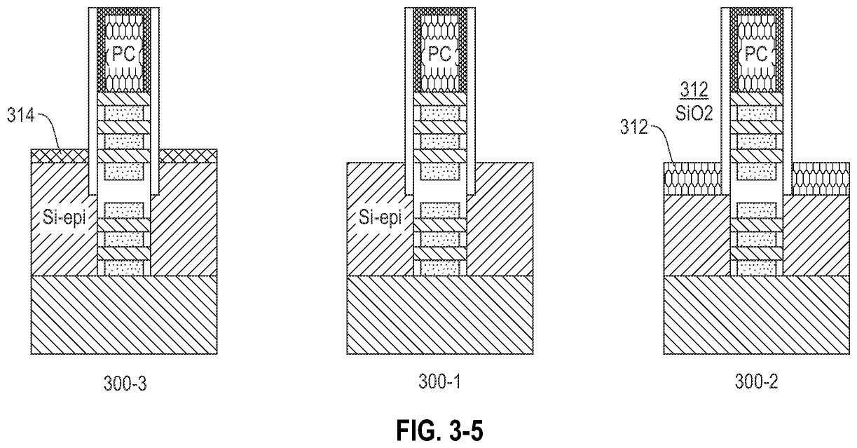

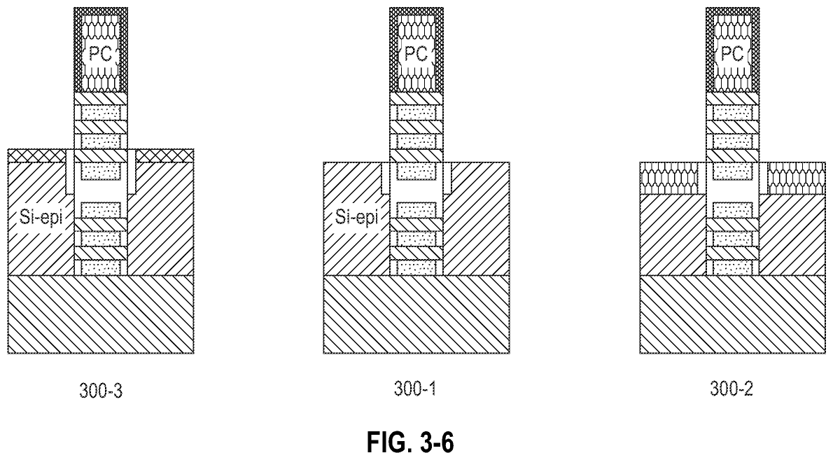

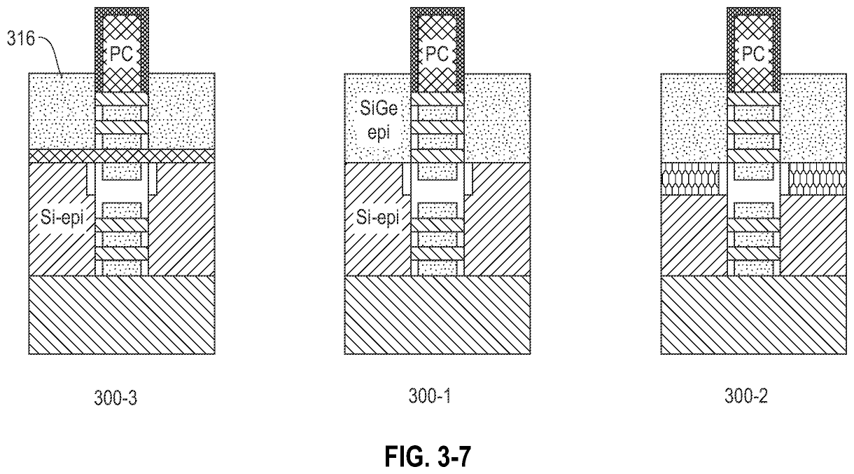

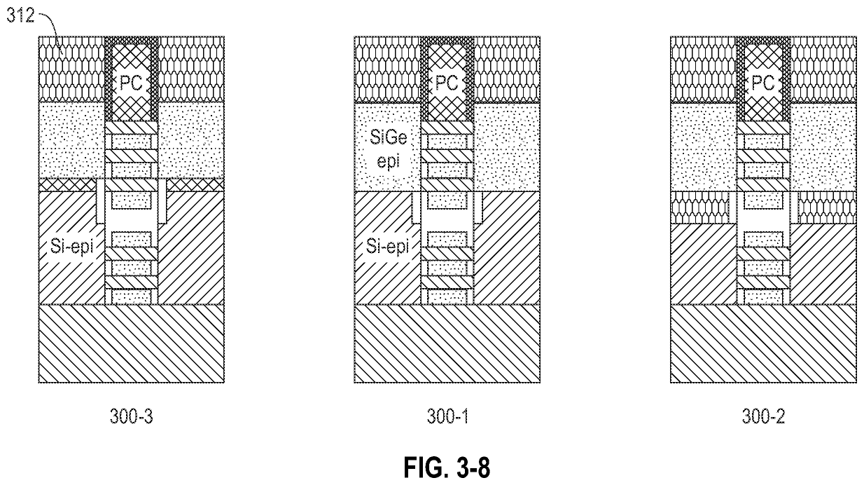

FIG. 3-1 is a cross-sectional view of a semiconductor structure during an intermediate step of a method of fabricating a protection diode 300-1 and a stacked FET 300-2, in accordance with some embodiments of the present disclosure. The stacked FET 300-2 represents a nominal stacked FET, for which the fabricated protection diode 300-1 provides protection from PID. Additionally, the method illustrated in FIGS. 3-1 through 3-8 represents a method for fabricating protection diodes, such as example protection diodes 100-1, 100-4. This view includes protection diode structure 300-1 and stacked FET structure 300-2. The protection diode structure 300-1 and stacked FET structure 300-2 each include a substrate 302, gate 304, silicon epitaxial 306, spacers 308, and organic planarization layer (OPL) 310. The gates 304 include a gate cap 304-1, silicon channels 304-2, and silicon germanium gate material 304-3, which could be changed to high k or work function metal (WFM) during a recess metal gate process.

FIG. 3-2 is a cross-sectional view of a semiconductor structure during an intermediate step of a method of fabricating a protection diode 300-1 and a stacked FET 300-2, in accordance with some embodiments of the present disclosure. This view represents the protection diode structure 300-1 and stacked FET structure 300-2 after EP patterning.

As shown, the EP patterning results in a removal of the OPL 310 and a portion of the ssilicon epitaxial 306 from the stacked FET structure 300-2. However, the protection diode structure 300-1 is unchanged.

FIG. 3-3 is a cross-sectional view of a semiconductor structure during an intermediate step of a method of fabricating a protection diode 300-1 and a stacked FET 300-2, in accordance with some embodiments of the present disclosure. This view represents the protection diode structure 300-1 and stacked FET structure 300-2 after OPL removal.

As shown, the EP patterning results in a removal of the OPL 310 from the protection diode structure 300-1. However, the stacked FET structure 300-2 is unchanged.

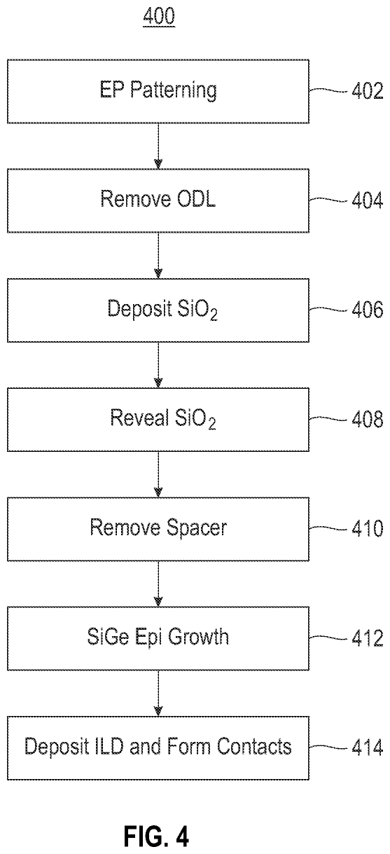

FIG. 3-4 is a cross-sectional view of a semiconductor structure during an intermediate step of a method of fabricating a protection diode 300-1 and a stacked FET 300-2, in accordance with some embodiments of the present disclosure. This view represents the protection diode structure 300-1 and stacked FET structure 300-2 after silicon dioxide (SiO₂) deposition. As shown, the silicon dioxide deposition results in a silicon dioxide layer 312 on the protection diode structure 300-1, and the stacked FET structure 300-2. More specifically, the silicon dioxide layer 312 is deposited over the silicon epitaxies 306, and surrounds the gates 304.

FIG. 3-5 is a cross-sectional view of a semiconductor structure during an intermediate step of a method of fabricating protection diodes 300-1, 300-3 and a stacked FET 300-2, in accordance with some embodiments of the present disclosure. As stated previously, the method illustrated in FIGS. 3-1 through 3-8 represent a method for fabricating protection diodes such as, example protection diodes 100-1, 100-4. While the intermediate steps illustrated in FIGS. 3-1 through 3-4 are applicable to example protection diodes 100-1, 100-4, the intermediate steps illustrated in FIGS. 3-5 through 3-8 differ for example protection diodes 100-1, 100-4. Accordingly, FIGS. 3-5 through 3-8 include protection diode structures 300-1, 300-3, where protection diode structure 300-1 represents fabrication of example protection diode 100-1, and protection diode structure 300-3 represents fabrication of example protection diode 100-4. It is noted that protection diode structures 300-1, 300-3 represent different example fabrications, where only one of the two structures is fabricated with the stacked FET structure 300-2.

This view represents the protection diode structure 300-1 and stacked FET structure 300-2 after a silicon oxide reveal. As shown, the silicon oxide reveal results in removal of the silicon oxide layer 312 from the protection diode structures 300-1,300-3, and a portion of the silicon oxide layer 312 from the stacked FET structure 300-2. Additionally, an intrinsic layer 314 is deposited over the silicon epitaxial 306 on the protection diode structure 300-3. As stated previously, the intrinsic layer 314 is an undoped epitaxial layer.

FIG. 3-6 is a cross-sectional view of a semiconductor structure during an intermediate step of a method of fabricating protection diodes 300-1, 300-3 and a stacked FET 300-2, in accordance with some embodiments of the present disclosure. This view represents the protection diode structures 300-1, 300-3 and stacked FET structure 300-2 after spacer removal. As shown, the spacer removal results in the removal of the exposed portions of the spacers 304-4 from the protection diode structures 300-1, 300-3, and the stacked FET structure 300-2. By merely removing the exposed portions of the spacers 304-4, the portions within the intrinsic layer 314 of the protection diode 300-3, the silicon epitaxial 306, and the silicon oxide layer 312, remain (as shown).

FIG. 3-7 is a cross-sectional view of a semiconductor structure during an intermediate step of a method of fabricating protection diodes 300-1, 300-3 and a stacked FET 300-2, in accordance with some embodiments of the present disclosure. This view represents the protection diode structures 300-1, 300-3, and stacked FET structure 300-2 after silicon germanium (SiGe) epitaxial growth. As shown, the silicon germanium epitaxial growth results in a silicon germanium layer 316 over the protection diode structures 300-1, 300-3, and stacked FET structure 300-2. More specifically, the silicon germanium epitaxial growth results in a silicon germanium layer 316 over the silicon epitaxial 306 of the protection diode structures 300-1, over the intrinsic layer 314 of the protection diode 300-3, and over the remaining silicon oxide layer 312 of the stacked FET structure 300-2.

FIG. 3-8 is a cross-sectional view of a semiconductor structure during an intermediate step of a method of fabricating protection diodes 300-1, 300-3 and a stacked FET 300-2, in accordance with some embodiments of the present disclosure. This view represents the protection diode structures 300-1, 300-3, and stacked FET structure 300-2 after ILD deposition and contact formation. ILD deposition may involve depositing the ILD layer 318 over the silicon germanium layers 316 of the protection diode structures 300-1, 300-3, and stacked FET structure 300-2. The contact formation may involve a known metal fill process providing electrical contact with the epitaxies. The contact formation involves a known metal fill process not discussed here. Further, the formed contacts are not shown.

FIG. 4 is a process flow chart of a method 400 for fabricating protection diodes 300-1, 300-3 and stacked FET 300-2, in accordance with some embodiments of the present disclosure. The method 400 may be similar to the method of fabricating protection diode 300-1, 300-3 and a stacked FET 300-2 described with respect to FIGS. 3-1 through 3-8.

At operation 402, a fabrication tool may perform EP patterning on a protection diode structure, such as the protection diode structure 300-1, and a stacked FET structure, such as, the stacked FET structure 300-2, described with respect to FIG. 3-1. Performing the EP patterning may involve removing the OPL 310 and a portion of the silicon epitaxial 306 from the stacked FET structure 300-2, while leaving the protection diode structure 300-1 unchanged.

At operation 404, a fabrication tool may remove the OPL layer on the protection diode structure 300-1, and stacked FET structure 300-2, described with respect to FIG. 3-2. Removing the OPL may involve removing the OPL 310 from the protection diode structure 300-1. However, the stacked FET structure 300-2 is unchanged.

At operation 406, a fabrication tool may deposit a silicon oxide layer on the protection diode structure 300-1, and stacked FET structure 300-2, described with respect to FIG. 3-3. Depositing the silicon oxide layer may involve depositing a layer of silicon oxide (e.g., silicon oxide layer 312) over the silicon epitaxies 306 of the protection diode structure 300-1, and the stacked FET structure 300-2.

At operation 408, a fabrication tool may reveal the SiO₂ layer on the protection diode structure 300-1, and stacked FET structure 300-2, described with respect to FIG. 3-4. Revealing the silicon oxide layer may involve removing the silicon oxide layer 312 from the protection diode structures 300-1,300-3, and a portion of the silicon oxide layer 312 from the stacked FET structure 300-2. Additionally, the silicon oxide removal may involve depositing an undoped epitaxial layer (e.g., intrinsic layer 314) over the silicon epitaxial layer 306 of the protection diode structure 300-3.

At operation 410, a fabrication tool may remove the spacers from the protection diode structures 300-1, 300-3, and stacked FET structure 300-2, described with respect to FIG. 3-5. Removing the spacers may involve removing the exposed portions of the spacers (e.g., spacers 304-4) from the protection diode structures 300-1, 300-3, and the stacked FET structure 300-2.

At operation 412, a fabrication tool may perform silicon germanium epitaxial growth on the protection diode structures 300-1, 300-3, and stacked FET structure 300-2, described with respect to FIG. 3-6. Performing the silicon germanium epitaxial growth may involve growing silicon germanium epitaxies over: the silicon epitaxial 306 of the protection diode structures 300-1, the intrinsic layer 314 of the protection diode 300-3, and the remaining silicon oxide layer 312 of the stacked FET structure 300-2. Alternatively, the epitaxial growth can involve silicon epitaxial growth with P+ doping.

At operation 414, a fabrication tool may deposit an ILD layer and form contacts on the protection diode structures 300-1, 300-3, and stacked FET structure 300-2, described with respect to FIG. 3-7. Depositing the ILD layer may involve depositing the ILD layer 318 over the silicon germanium layers 316 of the protection diode structures 300-1, 300-3, and stacked FET structure 300-2. The contact formation may involve a known metal fill process providing electrical contact with the epitaxies.

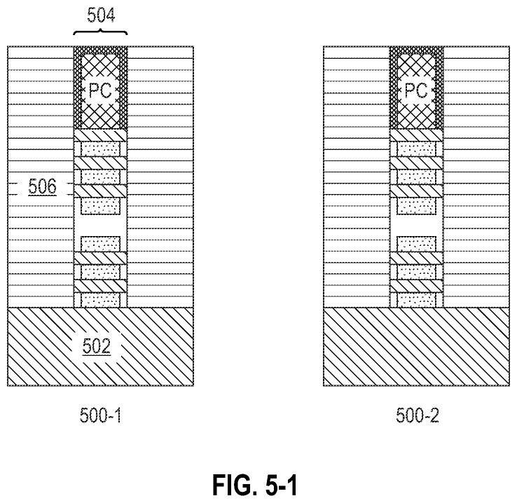

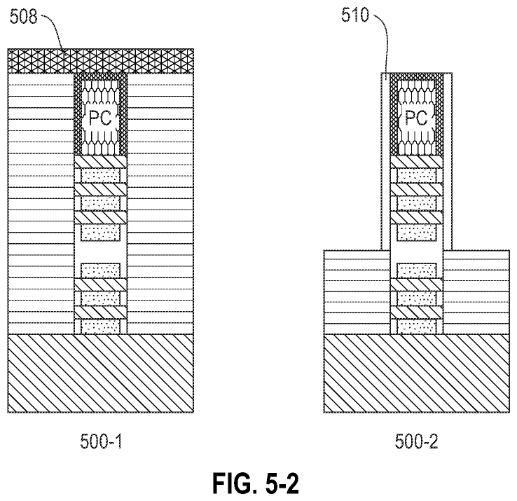

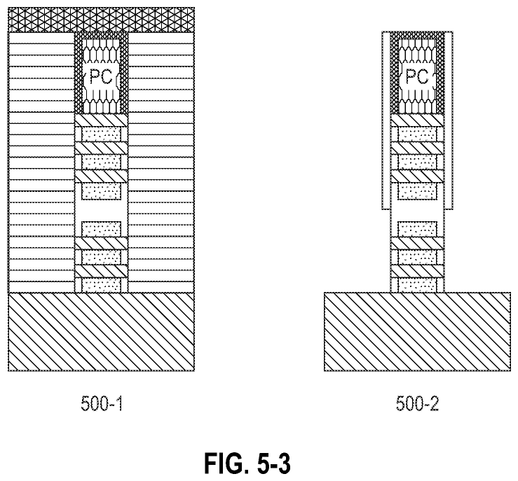

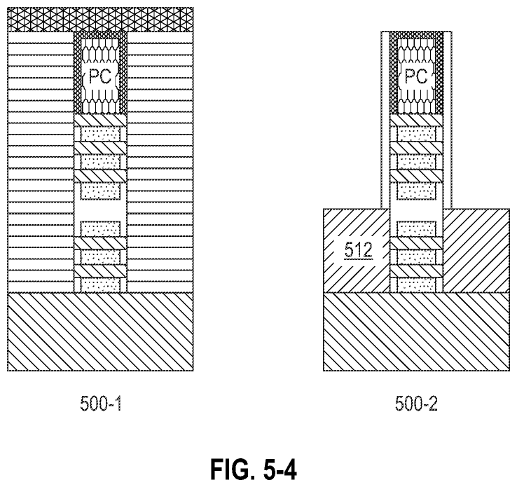

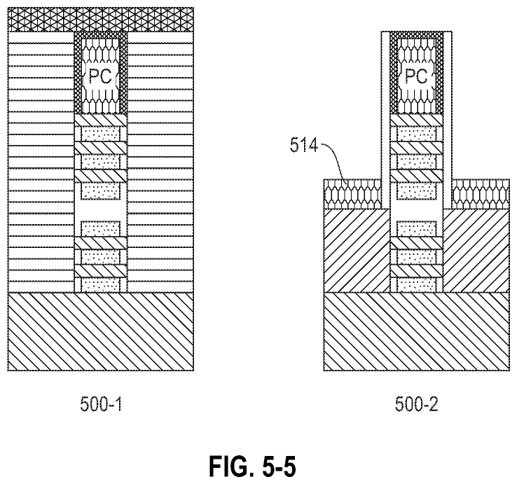

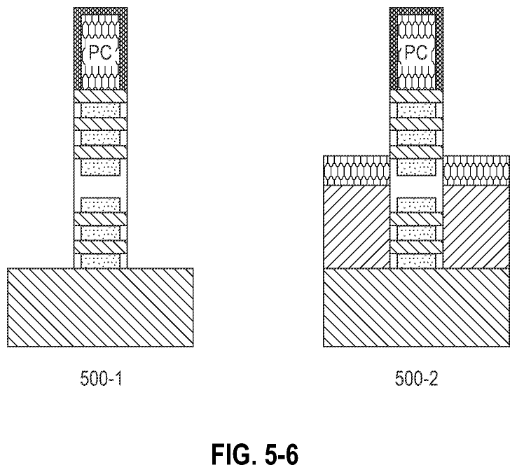

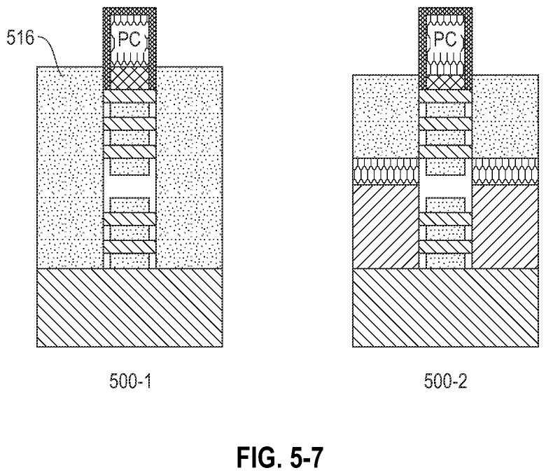

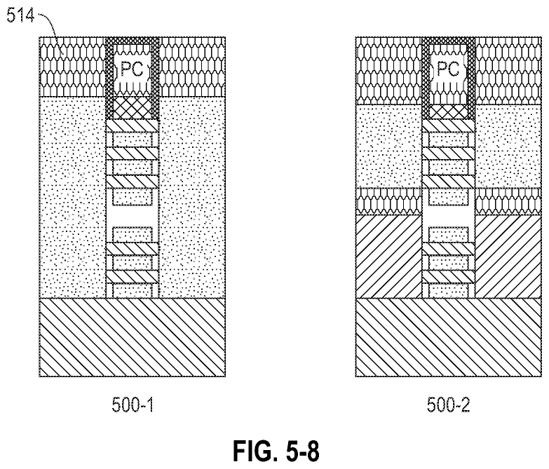

FIG. 5-1 is a cross-sectional view of a semiconductor structure during an intermediate step of a method of fabricating a protection diode 500-1 and a stacked FET 500-2, in accordance with some embodiments of the present disclosure. The stacked FET 500-2 represents a nominal stacked FET, for which the fabricated protection diode 500-1 provides protection from PID. Additionally, the method illustrated in FIGS. 5-1 through 5-8 represent a method for fabricating protection diodes, such as, example protection diode 100-2 described with respect to FIG. 1A. This cross-sectional view includes protection diode structure 500-1 and stacked FET structure 500-2. The protection diode structure 500-1 and stacked FET structure 500-2 each include a substrate 502, gate 504, and organic planarization layer (OPL) 506.

The substrate 502 may be similar to the substrate 302 described with respect to FIG. 3. Similarly, the gate 504 may be similar to the gate 504. The gate 504 may include a gate cap 304-1, silicon germanium (SiGe) sacrificial material 504-2, which will be replaced by high-k or WFM during a recess metal gate (RMG) process and silicon channels 504-3.

FIG. 5-2 is a cross-sectional view of a semiconductor structure during an intermediate step of a method of fabricating a protection diode 500-1 and a stacked FET 500-2, in accordance with some embodiments of the present disclosure. This view represents the protection diode structure 500-1 and stacked FET structure 500-2 after performing a block ESD patterning. With respect to the protection diode structure 500-1, patterning process involves depositing a mask 508 over the gate 504 and OPL 506. With respect to the stacked FET structure 500-2, ESD patterning process involves removing a portion of the OPL 506 and forming an ESD block 510 around the gate 504.

FIG. 5-3 is a cross-sectional view of a semiconductor structure during an intermediate step of a method of fabricating a protection diode 500-1 and a stacked FET 500-2, in accordance with some embodiments of the present disclosure. This view represents the protection diode structure 500-1 and stacked FET structure 500-2 after performing a recess. Performing the recess involves removing the remaining OPL 506 from the stacked FET structure 500-2. In comparison to FIG. 5-3, the protection diode structure 500-1 is unchanged.

FIG. 5-4 is a cross-sectional view of a semiconductor structure during an intermediate step of a method of fabricating a protection diode 500-1 and a stacked FET 500-2, in accordance with some embodiments of the present disclosure. This view represents the protection diode structure 500-1 and stacked FET structure 500-2 after forming n-type epitaxial (NEPI). Forming the NEPI can involve an n-type epitaxial growth over the substrate 502 of the stacked FET structure 500-2. As shown, the protection diode structure 500-1 is unchanged from FIG. 5-3. However, the stacked FET structure 500-2 additionally includes NEPI 512, which may be an epitaxial silicon.

FIG. 5-5 is a cross-sectional view of a semiconductor structure during an intermediate step of a method of fabricating a protection diode 500-1 and a stacked FET 500-2, in accordance with some embodiments of the present disclosure. This view represents the protection diode structure 500-1 and stacked FET structure 500-2 after forming an insulating layer and recess. The protection diode 500-1 is unchanged from FIG. 5-2. However, the stacked FET structure 500-2 additionally includes silicon oxide (SiO₂) layer 514. The recess can involve either a wet or dry etch, to remove some SiO₂ to a certain depth of the nanosheet in order to expose the top sheet after removing the liner.

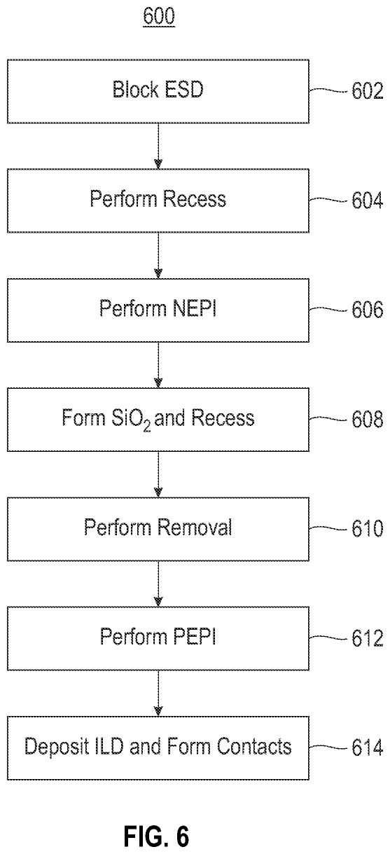

FIG. 5-6 is a cross-sectional view of a semiconductor structure during an intermediate step of a method of fabricating a protection diode 500-1 and a stacked FET 500-2, in accordance with some embodiments of the present disclosure. This view represents the protection diode structure 500-1 and stacked FET structure 500-2 after performing a removal process. In comparison to FIG. 5-5, the mask 508 and OPL 506 are removed from the protection diode structure 500-1. Further, the films in ESD block 510 is removed from the stacked FET structure 500-2.

FIG. 5-7 is a cross-sectional view of a semiconductor structure during an intermediate step of a method of fabricating a protection diode 500-1 and a stacked FET 500-2, in accordance with some embodiments of the present disclosure. This view represents the protection diode structure 500-1 and stacked FET structure 500-2 after performing a p-type epitaxial (PEPI) process. Performing the PEPI process can involve performing a p-type epitaxial growth over the substrate 502 of the protection diode structure 500-1, and the silicon oxide layer 514 of the stacked FET structure 500-2. As shown, in comparison to FIG. 5-6, the protection diode structure 500-1 and stacked FET structure 500-2 additionally include p-type epitaxies 516.

FIG. 5-8 is a cross-sectional view of a semiconductor structure during an intermediate step of a method of fabricating a protection diode 500-1 and a stacked FET 500-2, in accordance with some embodiments of the present disclosure. This view represents the protection diode structure 500-1 and stacked FET structure 500-2 after performing ILD deposition and contact formation. Performing ILD layer deposition may involve depositing an ILD layer 514 over the p-type epitaxies 516 of the protection diode structure 500-1 and stacked FET structure 500-2. The ILD layer 514 may be composed of silicon dioxide. The contact formation may involve a known metal fill process generating contacts that provide electrical contact with the p-type epitaxies 516. The resulting contacts are not shown in FIG. 5-8.

FIG. 6 is a process flow chart of a method for fabricating a protection diode 500-1 and a stacked FET 500-2, in accordance with some embodiments of the present disclosure. The method 600 may be similar to the method of fabricating a protection diode and a stacked FET described with respect to FIGS. 5-1 through 5-8.

At operation 602, a fabrication tool may perform a block ESD. Performing the block ESD may involve depositing a mask 508 over the gate 504 and OPL 506 of the protection diode structure 500-1. Further, with respect to the stacked FET structure 500-2, performing the block ESD may involve removing a portion of the OPL 506 and forming an ESD block area 510 around the gate 504.

At operation 604, a fabrication tool may perform a recess. Performing the recess may involve removing the remaining OPL 506 from the stacked FET structure 500-2.

At operation 606, a fabrication tool may perform NEPI. Performing NEPI may involve forming an n-type epitaxial (e.g., epitaxial silicon) on the stacked FET structure 500-2.

At operation 608, a fabrication tool may form a silicon oxide layer and perform a recess. Forming the silicon oxide layer may involve forming an insulating layer of silicon oxide (e.g., silicon oxide layer 514) over the silicon epitaxial 504 of the stacked FET structure 500-2.

At operation 610, a fabrication tool may perform a removal. Performing the removal may involve removing the mask 508 and OPL 506 from the protection diode structure 500-1, and the ESD block 510 is removed from the stacked FET structure 500-2.

At operation 612, a fabrication tool may perform a PEPI process. Performing the PEPI process may involve a p-type epitaxial growth over the substrate 504 of the protection diode, and the silicon oxide layer 514 of the stacked FET structure.

At operation 614, a fabrication tool may deposit ILD and form contacts. Depositing the ILD layer may involve depositing the ILD layer 514 over the p-type epitaxial layers of the protection diode structure 500-1, and stacked FET structure 500-2. The contact formation may involve a known metal fill process providing electrical contact with the p-type epitaxies.

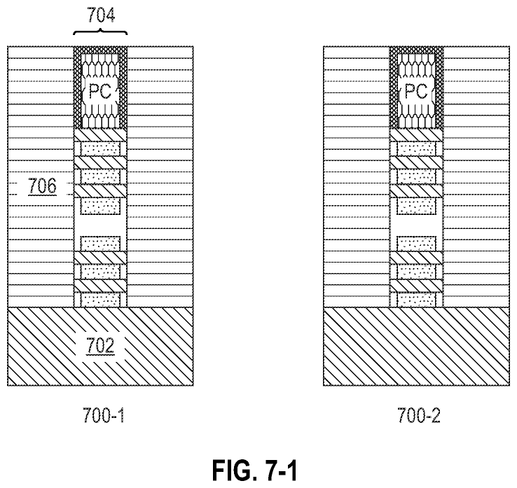

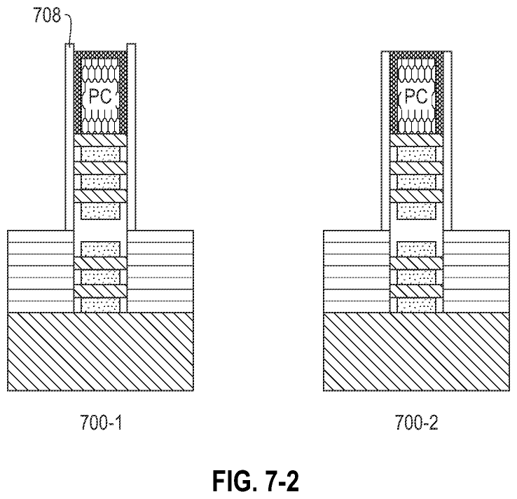

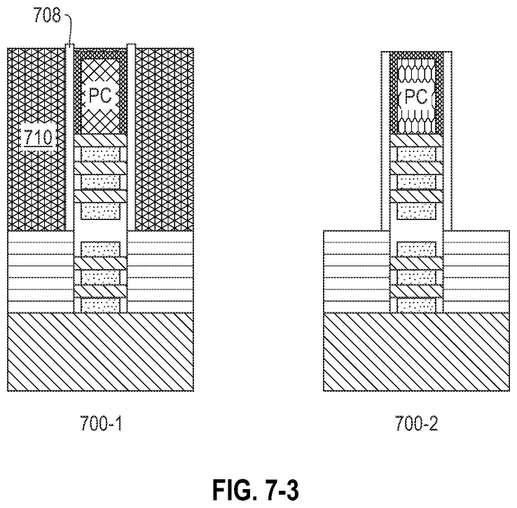

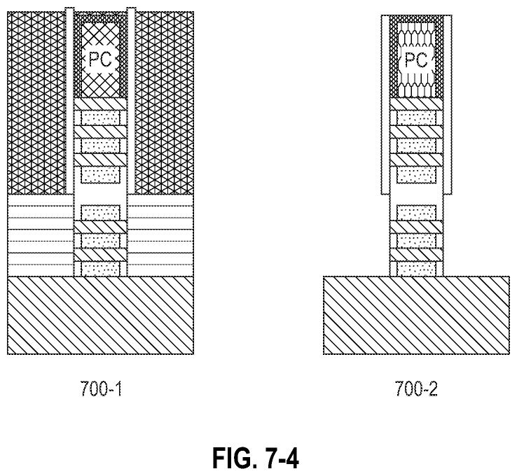

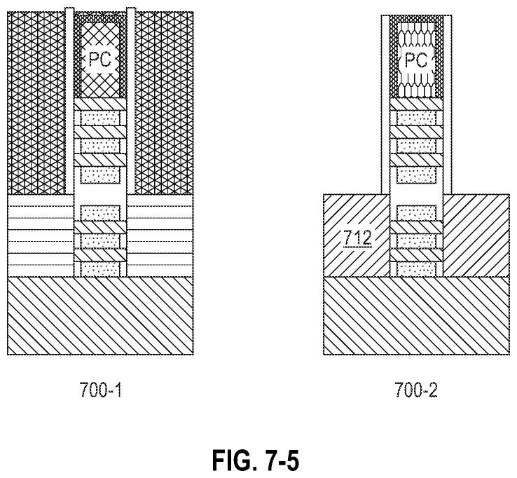

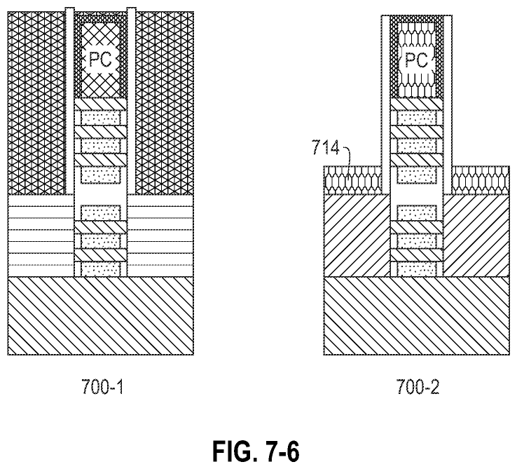

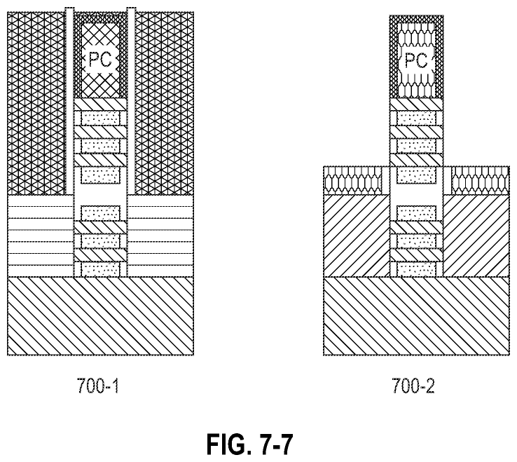

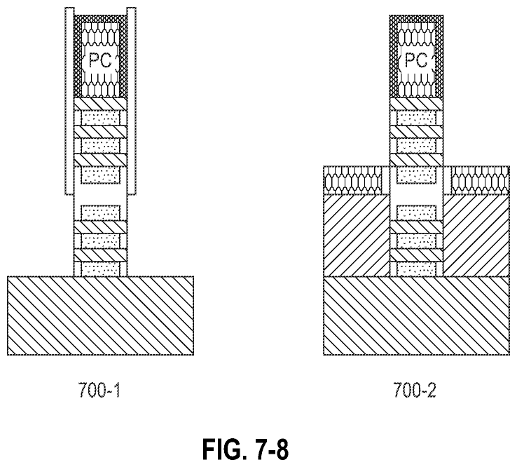

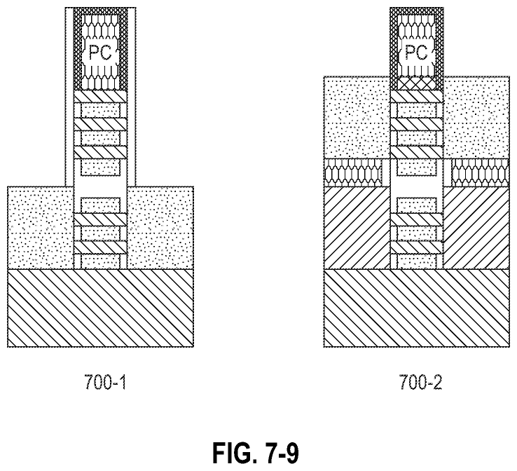

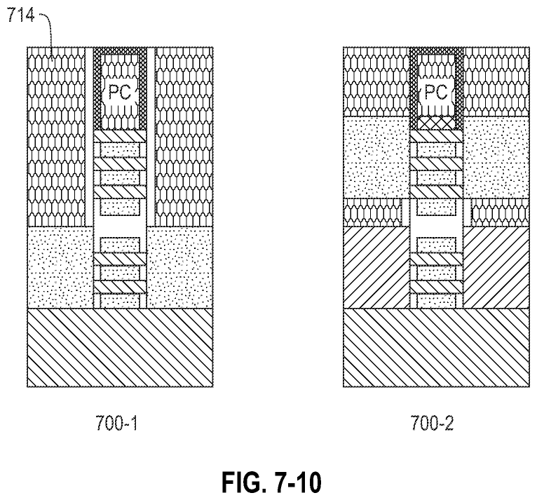

FIG. 7-1 is a cross-sectional view of a semiconductor structure during an intermediate step of a method of fabricating a protection diode 700-1 and a stacked FET 700-2, in accordance with some embodiments of the present disclosure. The stacked FET 700-2 represents a nominal stacked FET, for which the fabricated protection diode 700-1 provides protection from PID. Additionally, the method illustrated in FIGS. 7-1 through 7-10 represent a method for fabricating protection diodes, such as, example protection diode 100-3 described with respect to FIG. 1A. This cross-sectional view includes protection diode structure 700-1 and stacked FET structure 700-2. The protection diode structure 700-1 and stacked FET structure 700-2 each include a substrate 702, gate 704, and organic planarization layer (OPL) 706.

The substrate 702 may be similar to the substrate 502 described with respect to FIG. 5-1. Similarly, the gate 704 may be similar to the gate 504, and may include a gate cap 704-1, silicon germanium (SiGe) sacrificial material 704-2, which would be replaced with high-k/WFM during the RMG process, and silicon channels 704-3.

FIG. 7-2 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure 700-2 after performing a recess and forming a liner. Performing the recess may involve removing a portion of the OPL layer 706 from the protection diode structure 700-1 and stacked FET structure 700-2. The removed portions are illustrated in the comparison between FIGS. 7-1 and 7-2. Additionally, forming the liner may involve depositing a liner 708 around the exposed portions of the gates 704 of the protection diode structure 700-1 and the stacked FET structure 700-2.

FIG. 7-3 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure after performing an ESD patterning. Performing the ESD block may involve depositing a mask 710 over the remaining OPL 706, and surrounding the gate 704 of the protection diode structure 700-1. However, the stacked FET structure 700-2 is unchanged. in comparison to FIG. 7-2

FIG. 7-4 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure 700-2 after performing a recess. Performing the recess may involve removing the remaining OPL 706 from the stacked FET structure 700-2. However, the protection diode structure 700-1 remains unchanged in comparison to FIG. 7-3.

FIG. 7-5 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure 700-2 after performing an n-type epitaxial (NEPI) process. Performing the NEPI process can involve an n-type epitaxial growth over the substrate 702 of the stacked FET structure 700-2. As shown, the protection diode structure 700-1 is unchanged from FIG. 7-4. However, the stacked FET structure 700-2 additionally includes NEPI 712, which may be an epitaxial silicon.

FIG. 7-6 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure 700-2 after forming a silicon oxide layer 714 and recess. Forming the silicon oxide layer 714 can involve depositing a layer of silicon oxide over the NEPI 712. Performing the recess may involve a wet or dry etch to remove SiO₂ and leave certain THK as an isolation layer. As shown, the protection diode 700-1 is unchanged from FIG. 7-5. However, the stacked FET structure 700-2 additionally includes silicon oxide (SiO₂) layer 714.

FIG. 7-7 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure 700-2 after removing the liner. Removing the liner may involve an etching or mechanical removal of the liner 708 from the stacked FET structure 700-2.

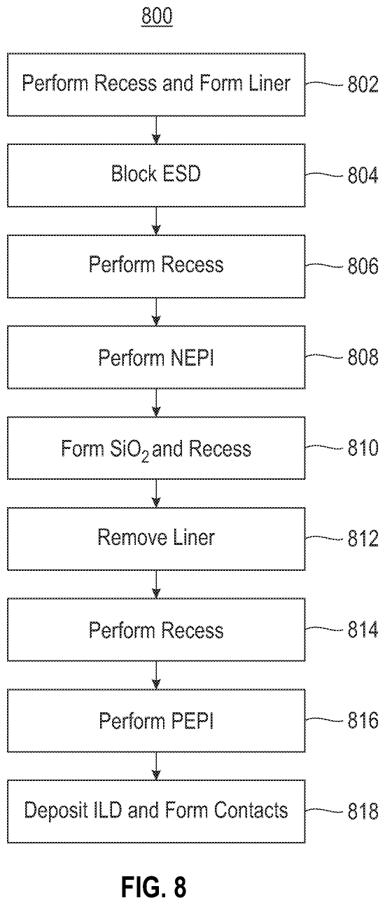

FIG. 7-8 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure 700-2 after performing a recess. Performing the recess may involve removing the mask 710 and the remaining OPL 706 from the protection diode structure 700-1. However, the stacked FET structure 700-2 remains unchanged in comparison to FIG. 7-7.

FIG. 7-9 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and stacked FET structure 700-2 after performing a p-type epitaxial (PEPI) process. Performing the PEPI process can involve performing a p-type epitaxial growth over the substrate 702 of the protection diode structure 700-1, and the silicon oxide layer 712 of the stacked FET structure 700-1. As shown, in comparison to FIG. 7-8, the protection diode structure 700-1 and stacked FET structure 700-2 additionally include p-type epitaxies 716.

FIG. 7-10 is a cross-sectional view of a semiconductor structure during an intermediate step of a method of fabricating a protection diode 700-1 and a stacked FET 700-2, in accordance with some embodiments of the present disclosure. This view represents the protection diode structure 700-1 and the stacked FET structure 700-2 after performing ILD deposition and contact formation. Performing ILD deposition may involve depositing the ILD layer 714 over the p-type epitaxies of the protection diode structure 700-1 and stacked FET structure 700-2.

FIG. 8 is a process flow chart of a method for fabricating a protection diode 700-1 and a stacked FET 700-2, in accordance with some embodiments of the present disclosure. The method 800 may be similar to the method of fabricating a protection diode 700-1 and a stacked FET 700-2 described with respect to FIGS. 7-1 through 7-10.

At operation 802, a fabrication tool may perform a recess and form a liner. Performing the recess may involve removing a portion of the OPL layer 706 from the protection diode structure 700-1 and stacked FET structure 700-2. Additionally, forming the liner may involve depositing a liner 708 around the exposed portions of the gates 704 of the protection diode structure 700-1 and the stacked FET structure 700-2.

At operation 804, a fabrication tool may perform a block ESD. Performing the block ESD may involve depositing a mask 710 surrounding the gate 704 and over the OPL 706 of the protection diode structure 700-1. Further, with respect to the stacked FET structure 700-2, performing the block ESD may involve removing a portion of the OPL 706 and forming an ESD block layer for protection diode on area of 710 around the gate 704.

At operation 806, a fabrication tool may perform a recess. Performing the recess may involve removing the remaining OPL 706 from the stacked FET structure 700-2.

At operation 808, a fabrication tool may perform a NEPI process. Performing the NEPI process may involve forming an n-type epitaxial (e.g., epitaxial silicon) on the stacked FET structure 700-2.

At operation 810, a fabrication tool may form a silicon oxide layer and perform a recess. Forming the silicon oxide layer may involve forming an insulating layer of silicon oxide (e.g., silicon oxide layer 714) over the silicon epitaxial 712 of the stacked FET structure 700-2. Performing the recess may involve a wet or dry etch to remove the SiO₂ and leave certain THK as an isolation layer.

At operation 812, a fabrication tool may remove the liner. Removing the liner may involve removing the liner 708 from the stacked FET structure 700-2.

At operation 814, a fabrication tool may perform a recess. Performing the recess may involve removing the mask 710 and OPL from the protection diode structure 700-1.

At operation 816, a fabrication tool may perform a PEPI process. Performing the PEPI process may involve a p-type epitaxial growth over the substrate 704 of the protection diode, and the silicon oxide layer 712 of the stacked FET structure.

At operation 818, a fabrication tool may deposit ILD and form contacts. Depositing the ILD layer may involve depositing the ILD layer 714 over the p-type epitaxial layers of the protection diode structure 700-1, and stacked FET structure 700-2. The contact formation may involve a known metal fill process providing electrical contact with the p-type epitaxies.

The terminology used herein is for the purpose of describing particular embodiments only and is not intended to be limiting of the various embodiments. As used herein, the singular forms “a.” “an,” and “the” are intended to include the plural forms as well, unless the context clearly indicates otherwise. It will be further understood that the terms “includes” and/or “including.” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks. When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category. For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations. Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor structure comprising:
a protection diode, the protection diode comprising:
a substrate;
a gate;
a first nanosheet layer, comprising a heavily doped n-type epitaxial disposed over the substrate, wherein the first nanosheet layer is in contact with the gate;
a second nanosheet layer comprising a heavily doped p-type epitaxial disposed over the substrate, wherein the second nanosheet layer is in contact with the gate, and wherein the first nanosheet layer and the second nanosheet layer surround the gate.

2. The semiconductor structure of claim 1, wherein the first nanosheet layer is disposed over the second nanosheet layer.

3. The semiconductor structure of claim 2, wherein the first nanosheet layer is in contact with the second nanosheet layer.

4. The semiconductor structure of claim 1, further comprising an intrinsic layer disposed between the first nanosheet layer and the second nanosheet layer, wherein the protection diode comprises a scaled PIN protection diode.

5. The semiconductor structure of claim 1, further comprising a first epitaxial contact in electrical contact with the first nanosheet layer.

6. The semiconductor structure of claim 5, further comprising a second epitaxial contact in electrical contact with the second nanosheet layer.

7. The semiconductor structure of claim 6, further comprising a metal line and a stacked field effect transistor (FET), wherein the metal line is in electrical contact with the first epitaxial contact and the stacked FET.

8. The semiconductor structure of claim 1, wherein the stacked FET comprises an n-type FET and a p-type FET.

9. A semiconductor structure comprising:
a protection diode, the protection diode comprising:
a substrate;
a gate;
a first nanosheet layer, comprising a heavily doped n-type epitaxial disposed over the substrate, and in contact with the gate;
a second nanosheet layer comprising a heavily doped p-type epitaxial disposed over the substrate, and in contact with the gate; and
an isolation layer that is disposed:
beneath the gate;
within the substrate; and
between the first nanosheet layer and the second nanosheet layer.

10. The semiconductor structure of claim 9, wherein the isolation layer isolates the first nanosheet layer from the second nanosheet layer.

11. The semiconductor structure of claim 10, wherein the isolation layer comprises an interlayer dielectric.

12. The semiconductor structure of claim 9, wherein the first nanosheet layer surrounds the gate with a corresponding nanosheet layer comprising the heavily doped n-type epitaxial disposed over the substrate.

13. The semiconductor structure of claim 12, further comprising a second epitaxial contact in electrical contact with the second nanosheet layer.

14. The semiconductor structure of claim 13, further comprising a metal line and a stacked field effect transistor (FET), wherein the metal line is in electrical contact with the first epitaxial contact and the stacked FET.

15. The semiconductor structure of claim 9, wherein the stacked FET comprises an n-type FET and a p-type FET.

16. A semiconductor structure comprising:
a protection diode, the protection diode comprising:
a substrate;
a gate;
a first nanosheet layer, comprising a heavily doped n-type epitaxial disposed over the substrate, wherein the first nanosheet layer is in contact with the gate;
a second nanosheet layer comprising a heavily doped p-type epitaxial disposed over the substrate, wherein the second nanosheet layer is in contact with the gate, and wherein the first nanosheet layer and the second nanosheet layer surround the gate, and wherein the first nanosheet layer is disposed over the second nanosheet layer, and wherein the first nanosheet layer is in contact with the second nanosheet layer; and
an intrinsic layer disposed between the first nanosheet layer and the second nanosheet layer, wherein the protection diode comprises a scaled PIN protection diode.

17. The semiconductor structure of claim 16, further comprising a first epitaxial contact in electrical contact with the first nanosheet layer.

18. The semiconductor structure of claim 17, further comprising a second epitaxial contact in electrical contact with the second nanosheet layer.

19. The semiconductor structure of claim 18, further comprising a metal line and a stacked field effect transistor (FET), wherein the metal line is in electrical contact with the first epitaxial contact and the stacked FET.

20. The semiconductor structure of claim 19, wherein the stacked FET comprises an n-type FET and a p-type FET.
